(19) United States
(12) Patent Application Publication
(10) Pub. No.: US 2023/0022355 A1
(43) Pub. Date: Jan. 26, 2023

(54) SEMICONDUCTOR STRUCTURE AND MANUFACTURING METHOD THEREOF

(71) Applicant: CHANGXIN MEMORY TECHNOLOGIES, INC., Hefei City (CN)

(72) Inventor: Qi WANG, Hefei City (CN)

(21) Appl. No.: 17/647,741

(22) Filed: Jan. 12, 2022

Related U.S. Application Data
(63) Continuation of application No. PCT/CN2021/117517, filed on Sep. 9, 2021.

(30) Foreign Application Priority Data
Jul. 22, 2021 (CN) 202110832234.2

(51) Int. Cl. H01L 49/02; H01L 21/02

(52) U.S. Cl. CPC H01L 28/91; H01L 21/02115; H01L 21/02271; H01L 21/0217

(57) ABSTRACT

The present disclosure relates to the technical field of semiconductors, and provides a semiconductor structure and a manufacturing method thereof. The semiconductor structure includes a substrate; a plurality of bottom electrodes, spaced apart from each other on the substrate; and a protective layer, located in upper portions of the bottom electrodes and separating the bottom electrodes. A material of the protective layer includes hard hydrogenated amorphous carbon.

### CROSS-REFERENCE TO RELATED APPLICATIONS

This is a continuation of International Application No. PCT/CN2021/117517, filed on Sep. 9, 2021, which claims the priority to Chinese Patent Application No. 202110832234.2, titled “SEMICONDUCTOR STRUCTURE AND MANUFACTURING METHOD THEREOF” and filed on Jul. 22, 2021. The entire contents of International Application No. PCT/CN2021/117517 and Chinese Patent Application No. 202110832234.2 are incorporated herein by reference.

### TECHNICAL FIELD

The present disclosure relates to the technical field of semiconductors, and in particular to a semiconductor structure and a manufacturing method thereof.

### BACKGROUND

In the related art, a bottom electrode of a capacitor of a semiconductor structure is supported through a laminated structure. Due to its own limitation, the laminated structure is prone to be destroyed in a process of forming a capacitor hole, thus affecting the subsequently formed bottom electrode of the capacitor.

### SUMMARY

According to a first aspect of the present disclosure, a semiconductor structure is provided, including:

a substrate;

a plurality of bottom electrodes, spaced apart from each other on the substrate; and

a protective layer, located in upper portions of the bottom electrodes and separating the bottom electrodes;

wherein a material of the protective layer includes hard hydrogenated amorphous carbon.

According to a second aspect of the present disclosure, a method of manufacturing a semiconductor structure is provided, including:

providing a substrate;

forming a laminated structure on the substrate; and

forming a plurality of capacitor holes in the laminated structure, the capacitor holes exposing the substrate;

wherein the laminated structure includes a protective layer, the protective layer forms upper portions of the capacitor holes, and a material of the protective layer includes hard hydrogenated amorphous carbon.

### BRIEF DESCRIPTION OF THE DRAWINGS

The preferred implementations of the present disclosure are described in detail below with reference to the accompanying drawings to make the objectives, features and advantages of the present disclosure more obvious. The drawings are merely exemplary illustrations of the present disclosure, and are not necessarily drawn to scale. The same reference numerals in the drawings always represent the same parts. In the drawings:

FIG. 1 is a schematic flowchart of a method of manufacturing a semiconductor structure according to an exemplary implementation;

FIG. 2 is a structural diagram of forming capacitor holes in a method of manufacturing a semiconductor structure according to an exemplary implementation;

FIG. 3 is a structural diagram of forming bottom electrodes in a method of manufacturing a semiconductor structure according to an exemplary implementation;

FIG. 4 is a structural diagram of removing a first sacrificial layer and a second sacrificial layer in a method of manufacturing a semiconductor structure according to an exemplary implementation;

FIG. 5 is a structural diagram of forming a dielectric layer in a method of manufacturing a semiconductor structure according to an exemplary implementation; and

FIG. 6 is a schematic structural diagram of a semiconductor structure according to an exemplary implementation.

### DETAILED DESCRIPTION

The typical embodiments embodying the features and advantages of the present disclosure are described in detail below. It should be understood that the present disclosure may have various changes in different embodiments, which do not depart from the scope of the present disclosure. The description and drawings herein are essentially used for the purpose of explanation, rather than limiting the present disclosure.

Different exemplary embodiments of the present disclosure are described below with reference to the accompanying drawings. The accompanying drawings form a part of the present disclosure, which show by way of example different exemplary structures, systems and steps that can implement various aspects of the present disclosure. It should be understood that other specific solutions of components, structures, exemplary devices, systems and steps may be used, and structural and functional modifications may be made without departing from the scope of the present disclosure. Moreover, although the terms such as “above”, “between” and “within” may be used in this specification to describe different exemplary features and elements of the present disclosure, these terms are used herein only for convenience of description, for example, according to the directions of the examples in the drawings. Nothing in this specification should be understood as requiring a specific three-dimensional direction of the structure to fall within the scope of the present disclosure.

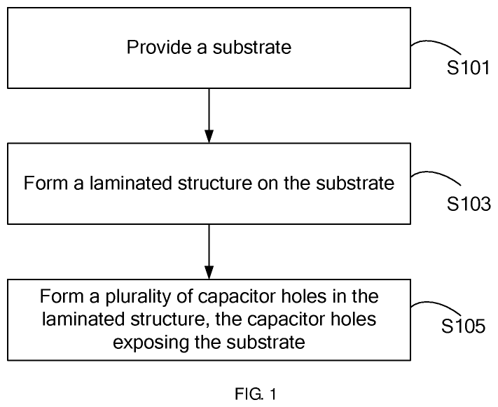

An embodiment of the present disclosure provides a method of manufacturing a semiconductor structure. With reference to FIG. 1, the method of manufacturing a semiconductor structure includes:

S101: Provide a substrate 10.

S103: Form a laminated structure 30 on the substrate 10.

S105: Form a plurality of capacitor holes 11 in the laminated structure 30, the capacitor holes 11 exposing the substrate 10.

The laminated structure 30 includes a protective layer 40, the protective layer 40 forms upper portions of the capacitor holes 11, and a material of the protective layer 40 includes hard hydrogenated amorphous carbon.

According to the method of manufacturing a semiconductor structure according to the embodiment of the present disclosure, the capacitor holes 11 are formed in the laminated structure 30, the laminated structure 30 includes the protective layer 40, and the protective layer 40 forms the upper portions of the capacitor holes 11. In addition, the material of the protective layer 40 includes the hard hydrogenated amorphous carbon, that is, the protective layer 40 has higher hardness. In this way, the protective layer 40 is not destroyed in the process of forming the capacitor holes 11, thus ensuring the quality of subsequently formed bottom electrodes 20 and improving the performance of the semiconductor structure.

It should be noted that the protective layer 40 formed by the hard hydrogenated amorphous carbon is a diamond-like carbon (DLC) film. The DLC film has excellent characteristics of diamond and graphite, and also has high hardness, high thermal conductivity and high electrical resistivity, good optical performance and excellent tribological characteristics. Therefore, the DLC film made of DLC is a metastable long-range disordered amorphous material, and carbon atoms are bonded through covalent bonds.

It should be noted that the substrate 10 may include a base 13 and a barrier layer 12. In addition, the laminated structure 30 is formed on the barrier layer 12, and the formed capacitor holes 11 expose the base 13. That is, the barrier layer 12 forms lower portions of the capacitor holes 11. A process for forming the capacitor holes 11 is not limited herein, and a process in the related art may be used, for example, a spacing multiplication technology is used to form the capacitor holes 11. In the process of forming the capacitor holes 11, the DLC film may not be destroyed due to its higher hardness.

The base 13 may include a portion made of a silicon-containing material. The base 13 may be made of any suitable material, including, for example, at least one from the group consisting of silicon, monocrystalline silicon, polysilicon, amorphous silicon, silicon-germanium, monocrystalline silicon-germanium, polycrystalline silicon-germanium, or carbon-doped silicon. The barrier layer 12 may include silicon nitride (SiN), silicon oxynitride (SiON), silicon carbon nitride (SiCN) or other materials.

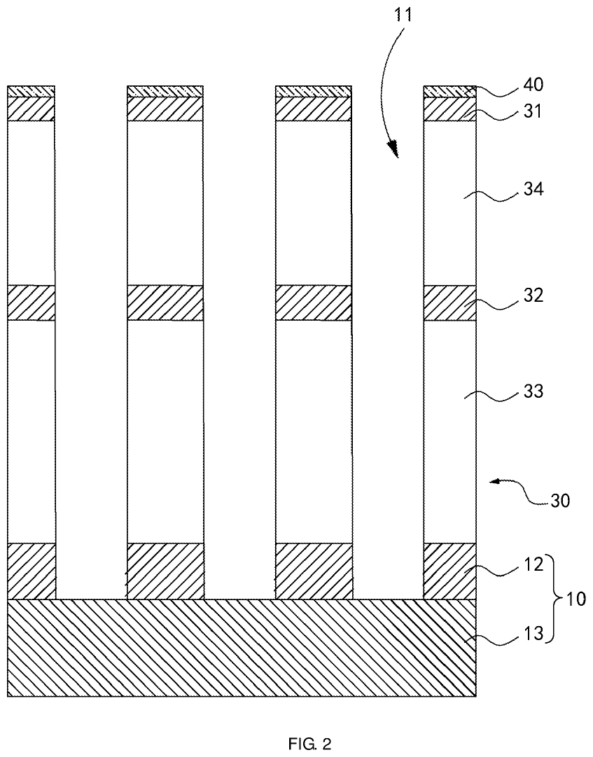

In an embodiment, as shown in FIG. 2, the laminated structure 30 further includes a first sacrificial layer 33, a second support layer 32, a second sacrificial layer 34 and a first support layer 31 that are sequentially formed on the substrate 10. The protective layer 40 is formed on the first support layer 31, and may protect the first support layer 31, such that the first support layer 31 is prevented from being destroyed in the process of forming the capacitor holes 11.

Specifically, the barrier layer 12 is formed on the base 13, the first sacrificial layer 33 is formed on the barrier layer 12, and the second support layer 32 is formed on the first sacrificial layer 33. In addition, the second sacrificial layer 34 is formed on the second support layer 32, and the first support layer 31 is formed on the second sacrificial layer 34. Finally, the protective layer 40 is formed on the first support layer 31. In this way, the laminated structure 30 is formed. Afterwards, the capacitor holes 11 are formed in the laminated structure 30, and at the moment, the capacitor holes 11 expose the base 13, as shown in FIG. 2.

For the foregoing embodiment, it should be noted that the barrier layer 12, the first sacrificial layer 33, the second support layer 32, the second sacrificial layer 34, the first support layer 31 and the protective layer 40 may be formed by using a physical vapor deposition process, a chemical vapor deposition process, or an atomic layer deposition process.

The barrier layer 12, the second support layer 32 and the first support layer 31 may be made of a same material, for example, silicon nitride (SiN), silicon oxynitride (SiON), silicon carbon nitride (SiCN) or other materials. Or the barrier layer 12, the second support layer 32 and the first support layer 31 may also be made of different materials.

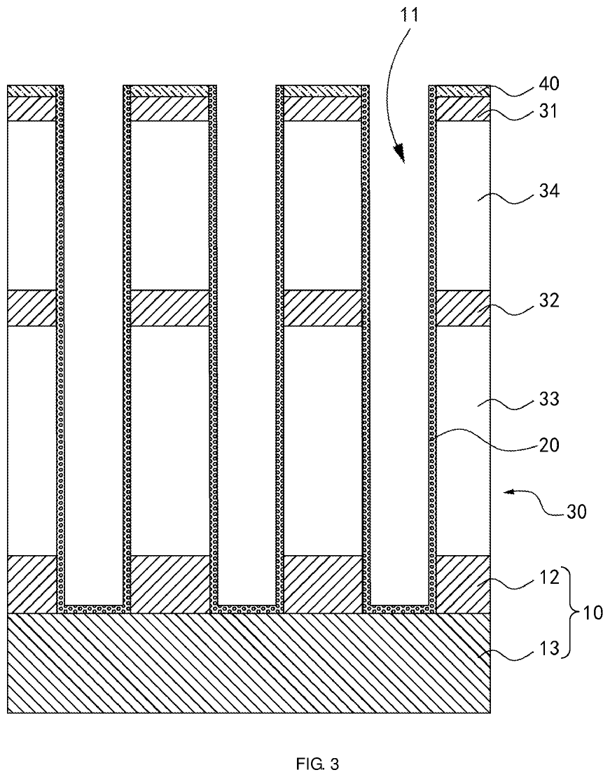

Optionally, the method of manufacturing a semiconductor structure further includes: forming bottom electrodes 20 in the capacitor holes 11. Bottoms of the bottom electrodes 20 are in direct contact with the substrate 10. At the moment, the bottom electrodes 20 cover side surfaces of the protective layer 40, and the bottoms of the bottom electrodes 20 are in direct contact with the base 13, as shown in FIG. 3.

Further, the protective layer 40 has a thickness less than a thickness of the first support layer 31, and the protective layer 40 mainly plays a protective role. In this way, the thickness of the protective layer 40 may be decreased as much as possible, so as to decrease the manufacturing cost of the semiconductor structure.

Optionally, the method of manufacturing a semiconductor structure further includes: removing the protective layer 40 after the capacitor holes 11 are formed; and forming the bottom electrodes 20 in the capacitor holes 11. The bottoms of the bottom electrodes 20 are in direct contact with the substrate 10. That is, in the process of forming the capacitor holes 11, the protective layer 40 achieves an effect of protecting the first support layer 31, and after the capacitor holes 11 are formed, the protective layer 40 may be removed. In addition, the protective layer 40 is prone to be removed due to the material including the hard hydrogenated amorphous carbon.

In an embodiment, the method of manufacturing a semiconductor structure further includes: removing the first sacrificial layer 33 and the second sacrificial layer 34 after the bottom electrodes 20 are formed; forming a dielectric layer 50 on surfaces of the bottom electrodes 20; and forming a top electrode 60 on a surface of the dielectric layer 50.

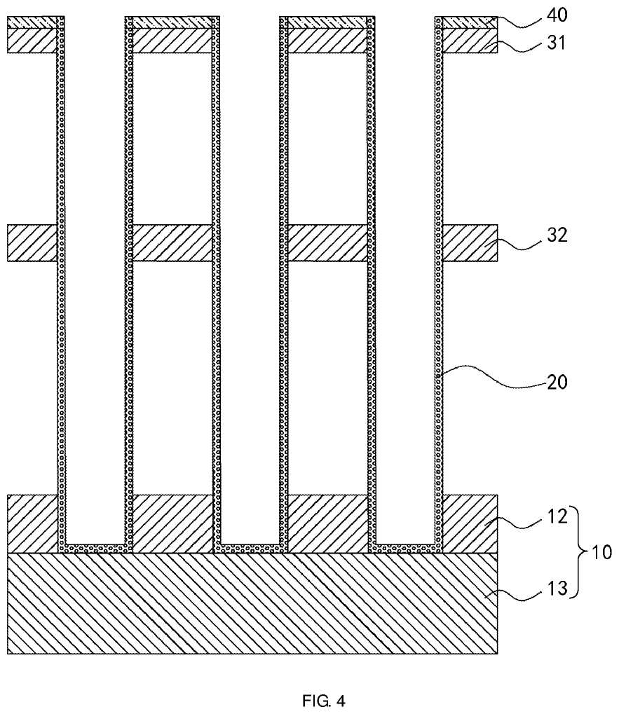

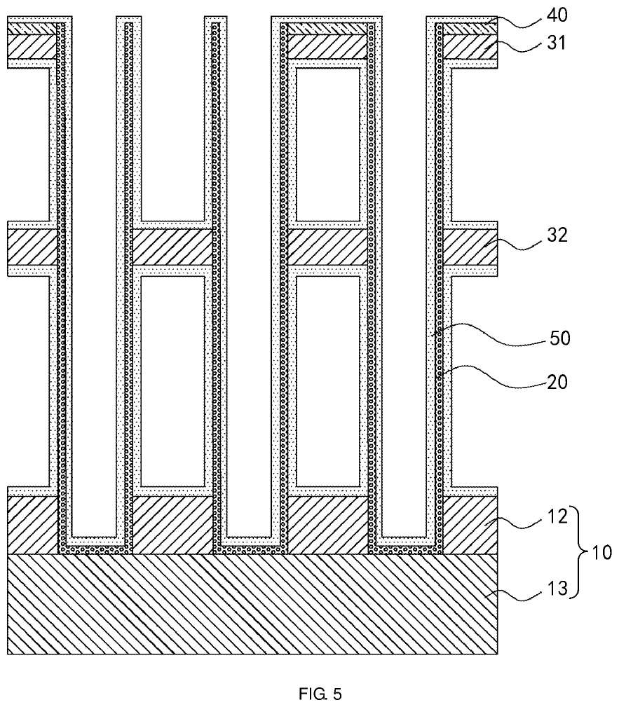

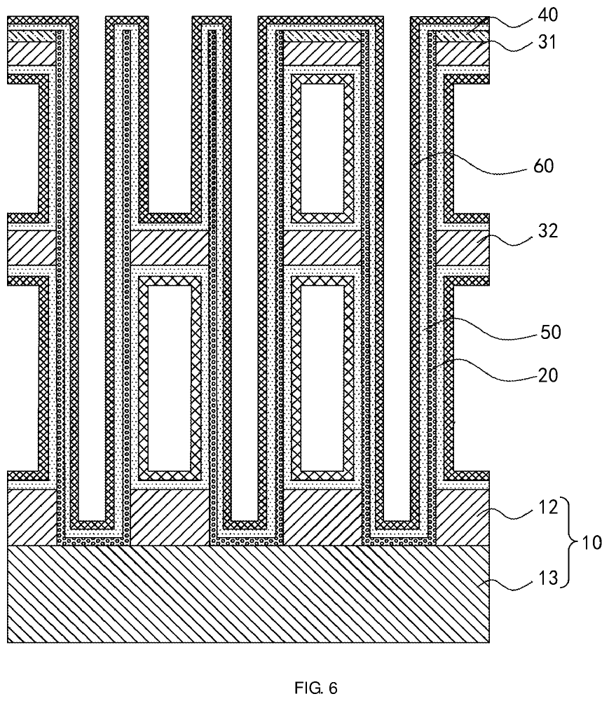

Specifically, after the structure as shown in FIG. 2 is formed, the bottom electrodes 20 are formed in the capacitor holes 11, as shown in FIG. 3, and the first sacrificial layer 33 and the second sacrificial layer 34 are removed. In addition, the protective layer 40, the first support layer 31, the second support layer 32 and the barrier layer 12 achieve an effect of supporting the bottom electrodes 20, as shown in FIG. 4. The dielectric layer 50 is formed on the surfaces of the bottom electrodes 20, and covers an upper surface of the protective layer 40, as shown in FIG. 5. Finally, the top electrode 60 is formed on the surface of the dielectric layer 50. For details, reference may be made to the semiconductor structure as shown in FIG. 6.

Optionally, if the protective layer 40 is removed after the capacitor holes 11 are formed, the formed dielectric layer 50 covers an upper surface of the first support layer 31.

Optionally, the base 13 includes a plurality of discrete contact pads, and the bottom electrodes 20 are in direct contact with the contact pads. A material of the contact pads includes, but is not limited to, tungsten (W).

It should be noted that the first sacrificial layer 33 and the second sacrificial layer 34 may be removed by using a wet etching process. A process for forming the bottom electrodes 20, the dielectric layer 50, and the top electrode 60 may be the physical vapor deposition process, the chemical vapor deposition process, or the atomic layer deposition process in the related art, which is not limited therein.

A material of the bottom electrodes 20 includes, but is not limited to, titanium nitride.

A material of the top electrode 60 includes, but is not limited to, titanium nitride.

A material of the dielectric layer 50 includes a high-k material, which includes, but is not limited to, at least one from the group consisting of alumina, zirconia, and hafnium oxide.

An embodiment of the present disclosure further provides a semiconductor structure. With reference to FIG. 6, the semiconductor structure includes a substrate 10; a plurality of bottom electrodes 20, spaced apart from each other on the substrate 10; and a protective layer 40, located in upper portions of the bottom electrodes 20 and separating the bottom electrodes 20. A material of the protective layer 40 includes hard hydrogenated amorphous carbon.

The semiconductor structure according to the embodiment of the present disclosure includes the substrate 10, the plurality of bottom electrodes 20 and the protective layer 40. In addition, the material of the protective layer 40 includes the hard hydrogenated amorphous carbon, that is, the protective layer 40 has higher hardness. In this way, the protective layer 40 is not destroyed in a process of forming capacitor holes 11, thus ensuring the quality of the bottom electrodes 20 and improving the performance of the semiconductor structure.

In an embodiment, the protective layer 40 is a DLC film layer, and has high hardness, high thermal conductivity and high electrical resistivity, good optical performance and excellent tribological characteristics.

Optionally, the hard hydrogenated amorphous carbon included in the protective layer 40 may be doped with other materials, for example, silicon nitride (SiN), silicon oxynitride (SiON), silicon carbon nitride (SiCN) or other materials, to facilitate connection with other structures of the laminated structure 30.

It should be noted that the substrate 10 may include a base 13 and a barrier layer 12. The barrier layer 12 forms lower portions of the capacitor holes 11.

The base 13 may include a portion made of a silicon-containing material. The base 13 may be made of any suitable material, including, for example, at least one from the group consisting of silicon, monocrystalline silicon, polysilicon, amorphous silicon, silicon-germanium, monocrystalline silicon-germanium, polycrystalline silicon-germanium, or carbon-doped silicon. The barrier layer 12 may include silicon nitride (SiN), silicon oxynitride (SiON), silicon carbon nitride (SiCN) or other materials.

In an embodiment, the semiconductor structure further includes a first support layer 31, located in middle portions of the bottom electrodes 20 and separating the bottom electrodes 20. The first support layer 31 may further achieve an effect of supporting the bottom electrodes 20.

Optionally, the first support layer 31 is spaced apart from the protective layer 40.

Optionally, the protective layer 40 covers a surface of the first support layer 31. That is, the protective layer 40 may achieve an effect of effectively protecting the first support layer 31, thus preventing the first support layer 31 from being destroyed in the process of forming the capacitor holes 11 through etching.

In an embodiment, the protective layer 40 has a thickness less than a thickness of the first support layer 31.

Optionally, the protective layer 40 has the thickness not greater than half the thickness of the first support layer 31. That is, a thinner layer of DLC film may achieve the effect of effectively protecting the first support layer 31. In addition, when the protective layer 40 is in contact with the first support layer 31, the first support layer 31 may achieve an effect of effectively supporting the bottom electrodes 20, such that the protective layer 40 may be thinner.

In an embodiment, as shown in FIG. 6, the semiconductor structure further includes a second support layer 32, located in the middle portions of the bottom electrodes 20 and separating the bottom electrodes 20. The second supporting layer 32 is located below the first support layer 31 and spaced apart from the first support layer 31.

Specifically, as shown in FIG. 6, the protective layer 40, the first support layer 31 and the second support layer 32 are sequentially arranged along a height direction. The protective layer 40 is in contact with the first support layer 31, and the first support layer 31 is spaced apart from the second support layer 32. In addition, the protective layer 40, the first support layer 31 and the second support layer 32 achieve the effect of supporting the bottom electrodes 20.

The barrier layer 12, the second support layer 32 and the first support layer 31 may be made of a same material, for example, silicon nitride (SiN), silicon oxynitride (SiON), silicon carbon nitride (SiCN) or other materials. Or the barrier layer 12, the second support layer 32 and the first support layer 31 may also be made of different materials.

It should be noted that a thickness relationship between the first support layer 31 and the second support layer 32 is not limited herein. The first support layer 31 may have a thickness equal to, or less than, or greater than a thickness of the second support layer 32.

In an embodiment, as shown in FIG. 6, the semiconductor structure further includes a dielectric layer 50, covering surfaces of the bottom electrodes 20; and a top electrode 60, covering a surface of the dielectric layer 50.

The substrate 10 may include the base 13 and the barrier layer 12. The barrier layer 12, together with the protective layer 40, the first support layer 31 and the second support layer 32, achieves an effect of supporting the bottom electrodes 20 and the top electrode 60.

Optionally, the dielectric layer 50 is arranged between the bottom electrodes 20 and the top electrode 60. A material of the dielectric layer 50 includes a high-k material, which includes, but is not limited to, alumina, zirconia, hafnium oxide or other high-k materials, or any combination thereof.

Optionally, a material of the bottom electrodes 20 includes, but is not limited to, titanium nitride.

Optionally, a material of the top electrode 60 includes, but is not limited to, titanium nitride.

In an embodiment, the substrate 10 includes a plurality of discrete contact pads. The bottom electrodes 20 are in direct contact with the contact pads, thus ensuring electrical connection between the bottom electrodes 20 and the contact pads.

Specifically, a material of the contact pads includes, but is not limited to, tungsten (W). The plurality of bottom electrodes 20 are arranged corresponding to the plurality of contact pads in a one-to-one manner.

It should be noted that the semiconductor structure in the embodiment is obtained through the method of manufacturing a semiconductor structure. For other materials and structures of the semiconductor structure in the embodiment, reference may be made to the method of manufacturing a semiconductor structure.

Those skilled in the art may easily figure out other implementations of the present disclosure after considering the specification and practicing the content disclosed herein. The present disclosure is intended to cover any variations, purposes or applicable changes of the present disclosure. Such variations, purposes or applicable changes follow the general principle of the present disclosure and include common knowledge or conventional technical means in the technical field which is not disclosed in the present disclosure. The specification and implementations are merely considered as illustrative, and the real scope and spirit of the present disclosure are directed by the appended claims.

It should be noted that, the present disclosure is not limited to the precise structures that have been described above and shown in the accompanying drawings, and can be modified and changed in many ways without departing from the scope of the present disclosure. The scope of the present disclosure is defined by the appended claims.

1. A semiconductor structure, comprising:
a substrate;
a plurality of bottom electrodes, spaced apart from each other on the substrate; and
a protective layer, located in upper portions of the bottom electrodes and separating the bottom electrodes;
wherein a material of the protective layer comprises hard hydrogenated amorphous carbon.

2. The semiconductor structure according to claim 1, wherein the protective layer is a diamond-like carbon film layer.

3. The semiconductor structure according to claim 1, wherein the semiconductor structure further comprises:
a first support layer, located in middle portions of the bottom electrodes and separating the bottom electrodes.

4. The semiconductor structure according to claim 3, wherein the protective layer covers a surface of the first support layer.

5. The semiconductor structure according to claim 4, wherein the protective layer has a thickness less than a thickness of the first support layer.

6. The semiconductor structure according to claim 5, wherein the protective layer has the thickness not greater than half the thickness of the first support layer.

7. The semiconductor structure according to claim 3, wherein the semiconductor structure further comprises:
a second support layer, located in the middle portions of the bottom electrodes and separating the bottom electrodes;
wherein the second support layer is located below the first support layer and spaced apart from the first support layer.

8. The semiconductor structure according to claim 7, wherein the semiconductor structure further comprises:
a dielectric layer, covering surfaces of the bottom electrodes; and
a top electrode, covering a surface of the dielectric layer.

9. The semiconductor structure according to claim 3, wherein the first support layer is spaced apart from the protective layer.

10. The semiconductor structure according to claim 1, wherein the substrate comprises a plurality of contact pads spaced apart from each other, and the bottom electrodes are in direct contact with the contact pads.

11. The semiconductor structure according to claim 1, wherein the hard hydrogenated amorphous carbon comprised in the protective layer can be doped with other materials.

12. The semiconductor structure according to claim 11, wherein the hard hydrogenated amorphous carbon can be doped with at least one from the group consisting of silicon nitride, silicon oxynitride or silicon carbon nitride.

13. A method of manufacturing a semiconductor structure, comprising:
providing a substrate;
forming a laminated structure on the substrate; and
forming a plurality of capacitor holes in the laminated structure, the capacitor holes exposing the substrate;
wherein the laminated structure comprises a protective layer, the protective layer forms upper portions of the capacitor holes, and a material of the protective layer comprises hard hydrogenated amorphous carbon.

14. The method of manufacturing a semiconductor structure according to claim 13, wherein the laminated structure further comprises a first sacrificial layer, a second support layer, a second sacrificial layer and a first support layer that are sequentially formed on the substrate;
wherein the protective layer is formed on the first support layer.

15. The method of manufacturing a semiconductor structure according to claim 14, further comprising:
forming bottom electrodes in the capacitor holes, bottoms of the bottom electrodes being in direct contact with the substrate.

16. The method of manufacturing a semiconductor structure according to claim 15, wherein the protective layer has a thickness less than a thickness of the first support layer.

17. The method of manufacturing a semiconductor structure according to claim 14, further comprising:
after the capacitor holes are formed,
removing the protective layer; and
forming bottom electrodes in the capacitor holes, bottoms of the bottom electrodes being in direct contact with the substrate.

18. The method of manufacturing a semiconductor structure according to claim 15, further comprising:
after the bottom electrodes are formed,
removing the first sacrificial layer and the second sacrificial layer;
forming a dielectric layer on surfaces of the bottom electrodes; and
forming a top electrode on a surface of the dielectric layer.

19. The method of manufacturing a semiconductor structure according to claim 13, wherein the substrate comprises a base and a barrier layer, the laminated structure is formed on the barrier layer, and the formed capacitor holes expose the base.

20. The method of manufacturing a semiconductor structure according to claim 13, wherein the protective layer is a diamond-like carbon film layer.
